(19) United States
(12) Patent Application Publication
(10) Pub. No.: US 2004/0072434 A1
(43) Pub. Date: Apr. 15, 2004

(54) Device manufacturing apparatus

(75) Inventor: Hiroyuki Maruyama, Tochigi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/675,997

(22) Filed: Oct. 2, 2003

(30) Foreign Application Priority Data
Oct. 10, 2002 (JP) 2002-297353

(51) Int. Cl. H01L 21/302; H01L 21/461

(52) U.S. Cl. 438/690

(57) ABSTRACT

In an apparatus having a plurality of objects to be cooled, cooling temperature adjustment is efficiently performed for the objects. A plurality of cooling temperature adjustment units (40, 50, 60) are provided to perform cooling temperature adjustment for a plurality of objects to be cooled (8, 14 (17), 15), respectively. Each of cooling temperature adjustment systems constituted by the plurality of cooling temperature adjustment units (40, 50, 60) includes the first cooling temperature adjustment system which uses any one coolant selected from the group consisting of pure water, a fluorine-based inert solution, a gas, and an antifreeze, and a second cooling temperature adjustment system which uses any one coolant which is selected from the group and is different from that used by the first cooling temperature adjustment system.

### FIELD OF THE INVENTION

The present invention relates to a device manufacturing apparatus and device manufacturing method and, more particularly, to a device manufacturing apparatus which has a plurality of objects subjected to temperature adjustment and a plurality of temperature adjustment systems which temperature-adjust them, and a device manufacturing method using the same.

### BACKGROUND OF THE INVENTION

As a conventional method of performing cooling temperature adjustment for a heating member of, for example, the driving section (e.g., a linear motor) of an alignment device mounted in an exposure apparatus, a temperature-managed fluorine-based inert solution is generally circulated through the heating member, as shown in FIG. 2. FIG. 2 shows an alignment device mounted in an exposure apparatus. The position of an object to be aligned (e.g., a wafer or reticle) 19 is measured using a measurement mirror 20 and a laser interferometer 21 at high precision. A linear motor including a stator 27 and a movable element 28 is kept at a constant temperature by circulating the fluorine-based inert solution.

As disclosed in Japanese Patent Laid-Open No. 10-309071, the linear motor has a jacket structure in which a coolant directly recovers the heat generated by a coil.

As the coolant, a fluorine-based inert coolant is used for the following reasons.

(1) The fluorine-based inert solution is a chemically stable liquid, does not degrade or decay, and does not require any maintenance.

(2) The fluorine-based inert solution does not induce any rust and form any rust in a pipe or at a joint. Even if this coolant leaks, it hardly influences the interior of the apparatus.

(3) The electrical insulating property of the fluorine-based inert solution is very high (about 10¹⁵ Ω·cm). Directly cooling a coil or the like does not impair the insulating property.

A circulation cooling technique for a coolant other than the fluorine-based inert solution adopts a gas coolant such as air or carbonic acid gas, an antifreeze coolant such as oil or brine (ethylene glycol-based or propylene glycol-based), or water containing various additives such as a rust preventive and preservative.

These days, stage acceleration is increasing along with an increase in processing sp ed (throughput). In addition, th mass of a stage increases along with an increase in size of a master and substrate. For this reason, a driving force defined by <mass of moving member>×<acceleration> becomes very large, and the heating value of a linear motor for stage driving increases. The influence of heat on the surroundings has obviously been posing a problem.

A manufacturing process for a semiconductor device such as an LSI or VLSI formed from a micropattern uses a reduction type projection exposure apparatus for printing by reduction projection a circuit pattern drawn on a master onto a substrate coated with a photosensitive agent. An increase in packaging density of semiconductor devices leads to further micropatterning. This requires high-precision alignment, and demands have arisen for suppressing the influence of heat generated by a linear motor on the measurement precision of an interferometer.

The fluorine-based inert coolant has advantages described in the prior art, but also has the following disadvantages.

(1) The unit cost is high.

(2) The warming potential is high.

(3) The heat capacity (specific heat x density) per unit volume is as small as about ½ that of wat r.

The unit cost of the fluorine-bas d inert solution is about 10 to 50 times higher than those of additive-containing water or various coolants such as brine. This increases the cost of an exposure apparatus which requires a large amount of coolant. The fluorine-based inert solution does not decompose even in air owing to high chemical stability. It is pointed out that the fluorine-based inert solution has a very high GWP (Global Warming Potential), and its use in large quantity is not preferable in terms of the global environment.

In addition to this, a higher-output driving unit and higher cooling ability are demanded especially for an exposure apparatus.

To improve the cooling ability, it is possible to

(1) increase the coolant flow rate,

(2) decrease the coolant temperature, or

(3) increase the heat capacity of the coolant.

As the coolant flow rate increases, necessary pump ability increases with its square. The pump becomes bulky, and a flow rate higher than before is difficult to ensure. If the flow rate of a coolant supplied to,near an object to be aligned as an object subjected to temperature control is set higher than the conventional value, the coolant forms turbulence, vibrating a pipe or the like. The vibrations cause a disturbance in an alignment control system, decreasing the alignment precision and furth r the xposure precision. At an excessively low coolant temperature, air around the coolant flow path becomes too low in comparison with the entire atmosphere, thereby causing nonuniformity in temperature. An interferometer laser for position measurement fluctuates in output, and the measurement precision and exposure precision decrease. From this, an alternate coolant with a large heat capacity in place of the fluorine-based inert solution has been demanded.

An example of such a large-heat-capacity coolant is water containing a rust preventive or preservative. This coolant is actually used in various machine tools. However, water containing a rust preventive or preservative does not have the electrical insulating property of a conventional fluorine-based inert coolant. This makes it difficult to adopt the above-mentioned structure of directly cooling an electrical component. Hence, a coolant which can ensure an electrical insulating property is required instead of a fluorine-based inert coolant.

A semiconductor factory must maintain a very clean space. Contamination of the atmosphere not only by a fine organic substance such as dust but also by metal ions or amine-based organic ions must be minimized in the semiconductor manufacturing process. Considering this, a coolant or the like used in the exposure apparatus d sirably contains no contaminants in case the coolant leaks.

From another point of view, in an apparatus having a plurality of objects subjected to cooling temperature adjustment, a plurality of temperature adjustment systems which perform cooling temperature adjustment for the objects conventionally use a common coolant. As described above, coolants such as a fluorine-based inert solution, a gas, an antifreeze, and the like have different characteristics. Thus, the inventor of the present invention has arrived at an idea that an apparatus having a plurality of objects subjected to cooling temperature adjustment preferably employs a coolant in accordance with the properties of the objects subjected to cooling temperature adjustment in consideration of the economical and physical efficiencies and the like.

### SUMMARY OF THE INVENTION

The present invention has been made in consideration of the above-mentioned background, and has as its object to, e.g., in an apparatus having a plurality of objects subjected to cooling temperature adjustment, efficiently perform cooling temperature adjustment for them.

According to the first aspect of the present inv ntion, there is provided a device manufacturing apparatus which has a plurality of objects to b temperature-adjusted, comprising a plurality of temperature adjustment systems for respectively temperature-adjusting the plurality of objects to be temperature-adjusted. The plurality of temperature adjustment systems are characterized by including a first temperature adjustment system which uses any one coolant selected from the group consisting of pure water, a fluorine-based inert solution, a gas, and an antifreeze, and a second temperature adjustment system which uses any one coolant which is selected from the group consisting of pure water, a fluorine based inert solution, a gas, and an antifreeze and is different from the coolant used by the first temperature adjustment system.

According to a preferred embodiment of the present invention, the first temperature adjustment system preferably uses pure water as a coolant. The first temperature adjustment system preferably has an impurity removing unit which removes an impurity in the pure water. Additionally, the first temperature adjustment system is preferably constituted by a closed path.

According to a preferred embodiment of the present invention, at least some (e.g., the first and second temperature adjustment systems) of the plurality of t mperature adjustment syst ms ar pr f rably arranged to operate independently.

According to a pr ferred embodiment of the present invention, each of the plurality of temperature adjustment systems preferably includes a temperature detection section which detects a temperature of a coolant, and a temperature controller which controls the temperature of the coolant on the basis of a temperature detected by the temperature detection section.

According to a preferred embodiment of the present invention, the apparatus can be configured as an exposure apparatus further including an exposure section which exposes a substrate to a pattern. Preferably, the exposure section includes a projection system which projects the pattern onto the substrate, and a stage device which has a driving section, and the first temperature adjustment system is arranged to temperature-adjust the driving section, and the second temperature adjustment system is arranged to temperature-adjust the projection system. Preferably, the plurality of temperature adjustment systems include a third temperature adjustment system which temperature-adjusts temperature adjustment air that circulates through the exposure section, and the third temperature adjustment system is arranged to use, as a coolant for temperature-adjusting the temperature adjustm nt air, a coolant different from a coolant used by the first and second temperature adjustment systems.

According to the second aspect of the present invention, there is provided a device manufacturing method characterized by comprising a step of processing a substrate by the above-mentioned device manufacturing apparatus.

According to the third aspect of the present invention, there is provided a device manufacturing method characterized by comprising a step of transferring a pattern onto a substrate using the above-mentioned device manufacturing apparatus.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a view showing the schematic arrangement of cooling equipment and a device manufacturing apparatus including th equipment according to a preferred embodiment of the present invention;

FIG. 2 is a diagram showing the concept of conventional cooling equipment;

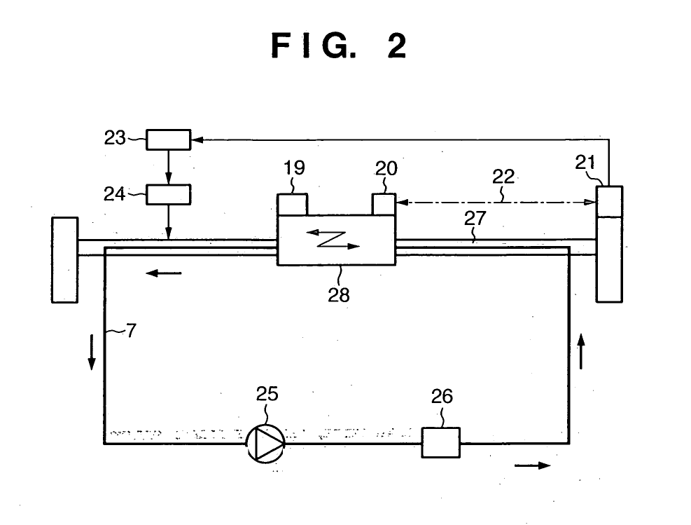

FIG. 3 is a flow chart showing the flow of the whole manufacturing process of a semiconductor device; and

FIG. 4 is a flow chart showing the detailed flow of the wafer process.

### DETAILED DESCRIPTION OF THE PREFERRED EMBODIMENTS

A preferred embodiment of the present invention will be described below.

According to the preferred embodiment of the present invention, a device manufacturing apparatus having a plurality of objects subjected to cooling temperature adjustment employs pure water, a fluorine-based inert solution, a gas, or an antifreeze as a coolant in accordance with the objects subjected to cooling temperature adjustment. The coolant to be employed can be determined in accordance with the properties (e.g., the heating value, the installation location, and the like) of the objects subjected to cooling temperature adjustment in consideration of the economical efficiency, physical efficiency (e.g., the recovery efficiency of heat), the size of the apparatus, and th like. This can provide a small efficient cooling temperature adjustment device which satisfies the required specifications.

Particularly, an object subjected to cooling temperature adjustment with a high heating value and/or an object subjected to cooling temperature adjustment which desirably does not emit heat to the surrounding atmosphere preferably employs pure water as the coolant. For example, if a device manufacturing apparatus having a driving section such as a linear motor, particularly, an exposure apparatus incorporates a cooling temperature adjustment device, a cooling temperature adjustment system which performs cooling temperature adjustment for the driving section preferably employs pure water as the coolant. In this case, an increase in cooling efficiency can suppress any degradation in performance (e.g., the alignment precision) of the exposure apparatus due to heat and can precisely transfer a fine pattern onto a substrate. The increase in cooling efficiency also contributes to an increase in stage velocity or the like and further an increase in processing speed (throughput). Additionally, pure water is excellent in views of economy.

Pure water is excellent as the coolant in that the heat capacity is large, the electrical insulating property is high, and that the device manufacturing process and the environment are fr from contamination or have no adverse eff cts. In order to obtain this advantage, the purity of pure wat r is preferably controlled to 1 MΩ·cm or more (0.1 μS/cm or less).

An object subjected to cooling temperature adjustment with a low heating value preferably employs a coolant other than pure water, such as a fluorine-based inert solution, a gas, or an antifreeze. To employ pure water as the coolant, the purity of pure water (water quality) needs to be kept at a predetermined level. For this purpose, an impurity removing unit is preferably provided. This, however, increases the size of the -cooling device. Under the circumstances, an object subjected to cooling temperature adjustment with a low heating value preferably employs a coolant which requires no impurity removing unit, i.e., a coolant whose properties (performance) can easily be maintained.

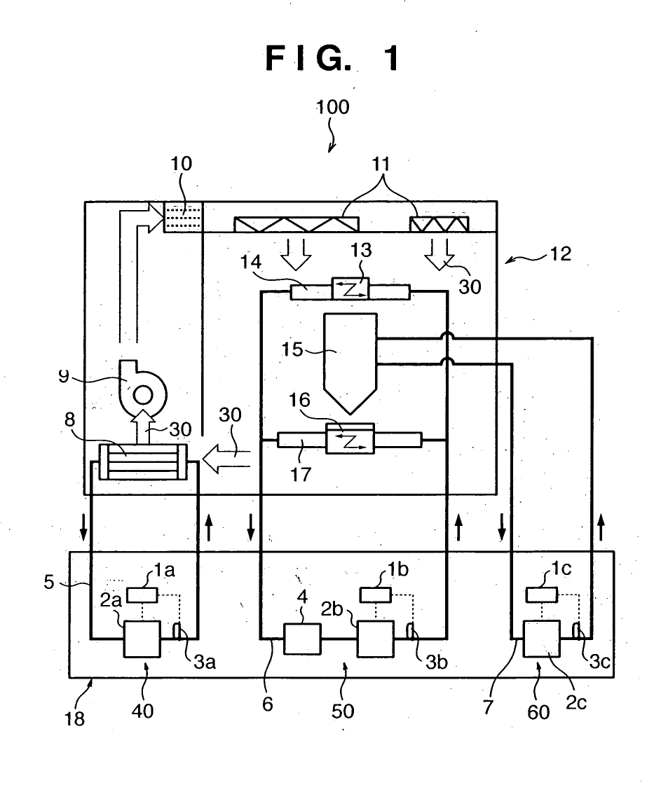

FIG. 1 is a view schematically showing the arrangement of an exposure apparatus (device manufacturing apparatus) according to the preferred embodiment of the present invention. An exposure apparatus 100 comprises cooling temperature adjustment equipment 18, which comprises a plurality of cooling temperature adjustment units 40, 50, and 60. The first cooling temperature adjustment unit 40 supplies a coolant to an air cooler 8 to perform cooling temperature adjustment for air 30, the second cooling temperature adjustm nt unit 50 supplies the coolant to a r ticl stage linear motor 14 and a wafer stage linear motor 17 to perform cooling temperature adjustment for them, and third cooling temperature adjustment unit 60 supplies the coolant to a lens (projection optical system) 15 to perform cooling temperature adjustment for the lens. Cooling temperature adjustment systems constituted by the first cooling temperature adjustment unit 40, second cooling temperature adjustment unit 50, and third cooling temperature adjustment unit 60 will be referred to as the first cooling temperature adjustment system, second cooling temperature adjustment system, and third cooling temperature adjustment system hereinafter, respectively.

The first cooling temperature adjustment system will be described first. In the exposure apparatus 100, the temperature adjustment air 30 circulates. The air 30 fed by an air fan 9 is heated again to a predetermined temperature by a heater 10, passes through a filter 11, and is fed into a chamber 12. The air 30 is heated by a heat source such as a linear motor while passing through the chamber 12 and is cooled by the air cooler 8.

An antifreeze which is controlled to have a predetermined temperature by the first cooling temperature adjustment unit 40 is supplied as the coolant to the air cooler 8 through an antifreeze path 5. The coolant may be a gas coolant, a so-called antifreeze coolant such as oil or brine (ethylene glycol-based or propylene glycol-based), or water containing a rust preventive and preservative. These coolants require little trouble in maintenance and management, have high maintainability, and cost less.

The second cooling temperature adjustment system will be described next. A heating portion with a high heating value such as the reticle stage linear motor 14 which drives a reticle stage 13 or the wafer stage linear motor 17 which drives a wafer stage 16 employs as the cooling medium pure water, which has a heat capacity about twice as large as that of a conventional and general fluorine-based inert coolant. This can suppress an increase in flow rate of the cooling medium.

It is desirable for the coolant for performing cooling temperature adjustment for a heating member such as a linear motor not only to have high electrical insulating property and high corrosion resistance but also not to contain contaminants in case the coolant leaks. Under the circumstances, the second cooling system preferably employs pure water with a resistivity of 1 MΩ·cm or more.

An impurity removing unit 4 is provided in a pure water path 6 which includes the second cooling temperature adjustment unit 50. The impurity removing unit 4 comprises all or some of, e.g., a deaeration film, an ion-exchange resin, a reverse osmosis membrane, an activated carbon filter, a membrane filter, bactericidal lamp, and the like. To remove dissolved oxygen in pure water, a method of providing a tank for storing pure water in the pure water path 6, filling the space in the tank with nitrogen, and removing dissolved oxygen in the pure water or a bubbling method of causing nitrogen to emit from the lower surface of the tank may be used.

By forming the pure water path 6 as a complete circulating system, i.e., closed system, the size of the second cooling temperature adjustment unit 50 and further the entire exposure apparatus can be reduced, as compared to a system in which pure water is externally supplied whenever necessary. This is because a complete circulating system can reduce a burden which the impurity removing unit 4 needs to carry in order to maintain the purity.

The third cooling temperature adjustment system will be described. A portion which is preferably less affected by leakage of the cooling medium or a portion which needs to ensure very high electrical insulating property preferably employs a fluorine-based inert coolant as the cooling medium. The fluorine-based in rt coolant is controlled by the third cooling temperature adjustment unit 60 to have a pr determined temperature and supplied to the 1 ns 15 through a fluorine-based inert coolant path 7. Since the fluorine-based inert coolant is a chemically stable liquid, it does not degrade or perish and requires almost no maintenance.

The cooling temperature adjustment units 40, 50, and 60 are preferably arranged to operate independently of each other. With this arrangement, for example, if the exposure apparatus suspends for a long period of time, and only the first cooling temperature adjustment unit 40 is operated, the quality (purity) of pure water can be maintained while suppressing the power consumption of the entire exposure apparatus.

The cooling temperature adjustment units 40, 50, and 60 comprise temperature controllers 1 (1a, 1b, and 1c), temperature adjustment sections 2 (2a, 2b, and 2c), and temperature detection sections 3 (3a, 3b, and 3c), respectively, to control the coolant to a predetermined temperature. The temperature controller 1 controls the temperature adjustment section 2 on the basis of a temperature detected by the temperature detection section 3 and supplies the coolant at a predetermined temperature to the units in the exposure apparatus.

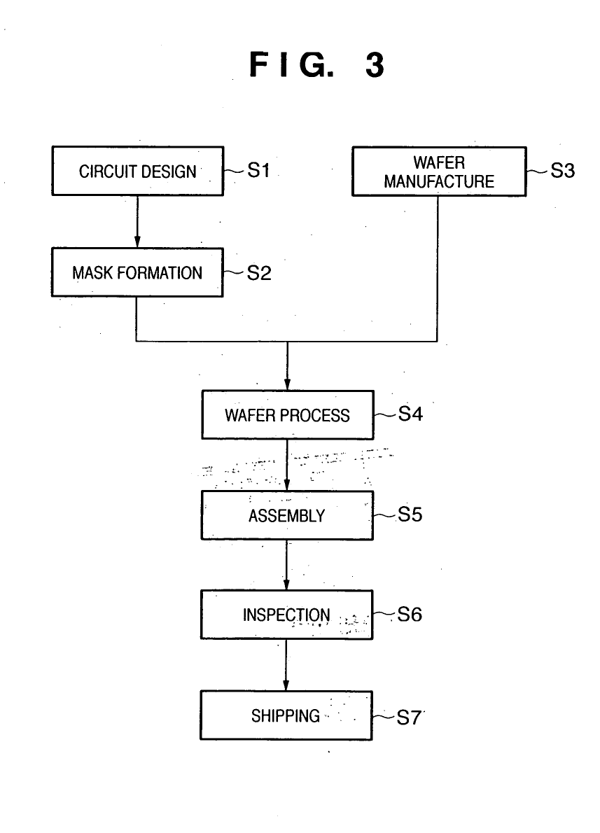

The manufacturing process of a semiconductor devic using the above-m ntioned exposure apparatus will be d scribed next. FIG. 3 shows the flow of the whole manufacturing process of the semiconductor device. In step 1 (circuit design), a semiconductor device circuit is designed. In step 2 (mask formation), a mask having the designed circuit pattern is formed. In step 3 (wafer manufacture), a wafer is manufactured by using a material such as silicon. In step 4 (wafer process) called a preprocess, an actual circuit is formed on the wafer by lithography using the prepared mask and wafer. Step 5 (assembly) called a post-process is the step of forming a semiconductor chip by using the wafer formed in step 4, and includes an assembly process (dicing and bonding) and packaging process (chip encapsulation). In step 6 (inspection), the semiconductor device manufactured in step 5 undergoes inspections such as an operation confirmation test and durability test of the semiconductor device manufactured in step 5. After these steps, the semiconductor device is completed and shipped (step 7).

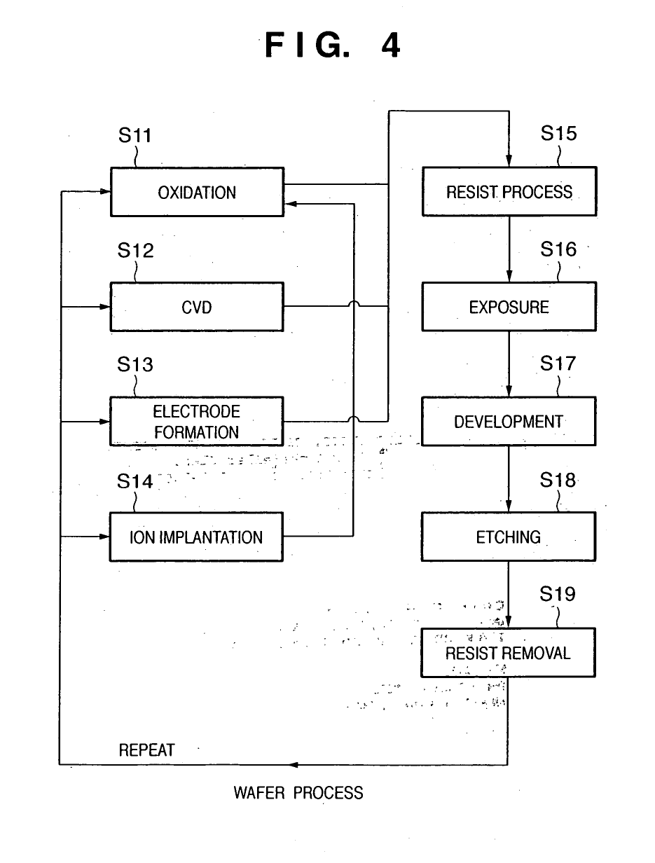

FIG. 4 shows the detailed flow of the above-mentioned wafer process. In step 11 (oxidation), the wafer surface is oxidized. In step 12 (CVD), an insulating film is formed on the wafer surface. In step 13 (electrode formation), an electrode is formed on the wafer by vapor deposition. In step 14 (ion implantation), ions are implanted in the wafer. In st p 15 (resist processing), a photosensitive agent is applied to the wafer. In st p 16 (exposure), the circuit pattern is transferred onto the wafer using the above-mentioned exposure apparatuses. In step 17 (development), the exposed wafer is developed. In step 18 (etching), the resist is etched except for the developed resist image. In step 19 (resist removal), an unnecessary resist after etching is removed. These steps are repeated to form multiple circuit patterns on the wafer.

According to the present invention, in an apparatus having a plurality of objects to be cooled, the objects can efficiently be cooled.

As many apparently widely different embodiments of the present invention can be made without departing from the spirit and scope thereof, it is to be understood that the invention is not limited to the specific embodiments thereof except as defined in the appended claims.

What is claimed is:

1. A device manufacturing apparatus which has a plurality of objects to be temperature-adjusted, comprising
a plurality of temperature adjustment systems which respectively temperature-adjust the plurality of objects to be temperature-adjusted,
wherein said plurality of temperature adjustment systems include
a first temperature adjustment system which uses any one coolant selected from the group consisting of pure water, a fluorine-based inert solution, a gas, and an antifreeze, and
a second temperature adjustment system which uses any one coolant which is selected from the group consisting of pure water, a fluorine based inert solution, a gas, and an antifreeze and is different from the coolant used by the first temperature adjustment system.

2. The apparatus according to claim 1, wherein the first temperature adjustment system uses pure water as a coolant and has an impurity removing unit which removes an impurity in the pure water.

3. The apparatus according to claim 1, wherein the first temperature adjustment system is constituted by a closed path.

4. The apparatus according to claim 1, wherein at least some of said plurality of t mperature adjustment systems are arranged to operate independently.

5. The apparatus according to claim 1, wherein each of said plurality of temperature adjustment systems includes
a temperature detection section which detect a temperature of a coolant, and
a temperature controller which controls the temperature of the coolant on the basis of a temperature detected by the temperature detection section.

6. The apparatus according to claim 1, wherein the apparatus is configured as an exposure apparatus further including an exposure section which exposes a substrate to a pattern.

7. The apparatus according to claim 6, wherein
the exposure section includes
a projection system which projects the pattern onto the substrate, and
a stage device which has a driving section, and
the first temperature adjustment system is arranged to temperature-adjust the driving section, and
the second temperature adjustment system is arranged to temperature-adjust the projection system.

8. The apparatus according to claim 6, wherein said plurality of temp rature adjustment systems include a third t mperature adjustment syst m which temperature-adjusts temperature adjustment air that circulates through the exposure section, and the third temperature adjustment system is arranged to use, as a coolant for temperature-adjusting the temperature adjustment air, a coolant different from a coolant used by the first and second temperature adjustment systems.

9. A device manufacturing method comprising a step of processing a substrate by a device manufacturing apparatus as defined in claim 1.

10. A device manufacturing method comprising a step of transferring a pattern onto a substrate using a device manufacturing apparatus as defined in claim 6.
